(19) United States
(12) Patent Application Publication
(10) Pub. No.: US 2016/0079069 A1
(43) Pub. Date: Mar. 17, 2016

(54) SEMICONDUCTOR MEMORY DEVICE AND METHOD FOR MANUFACTURING THE SAME

(71) Applicant: Kabushiki Kaisha Toshiba, Minato-ku (JP)

(72) Inventors: Tsuneo UENAKA, Yokkaichi (JP); Ryota Katsumata, Yokkaichi (JP)

(73) Assignee: Kabushiki Kaisha Toshiba, Minato-ku (JP)

(21) Appl. No.: 14/811,101

(22) Filed: Jul. 28, 2015

(30) Foreign Application Priority Data
Sep. 16, 2014 (JP) 2014-187501

(51) Int. Cl. H01L 21/28; H01L 29/40; H01L 27/115

(52) U.S. Cl. CPC H01L 21/28282; H01L 27/11582; H01L 27/11568; H01L 27/11573; H01L 29/401

(57) ABSTRACT

According to one embodiment, a memory device includes: a first insulating film, a first electrode, a second insulating film, and a second electrode being stacked in a multilayer body, and an end of the first electrode extending outside a region directly under the second electrode in an end of the multilayer body; a pillar piercing the first electrode and the second electrode; a memory film between the first electrode and the pillar, between the second electrode and the pillar, and being capable of storing a charge; an insulating film on the end of the multilayer body; and a contact piercing the insulating film, and being connected to the end of the first electrode film. A first portion connected to the contact in the first electrode film includes a metal or a metal nitride. A second portion surrounding the memory film in the first electrode film includes silicon.

### CROSS-REFERENCE TO RELATED APPLICATIONS

This application is based upon and claims the benefit of priority from Japanese Patent Application No. 2014-187501, filed on Sep. 16, 2014; the entire contents of which are incorporated herein by reference.

### FIELD

Embodiments described herein relate generally to a semiconductor memory device and a method for manufacturing the same.

### BACKGROUND

Conventionally, a stacked type semiconductor memory device has been proposed. In such the device, a stacked body, where a plurality of electrode films are stacked, is formed, and a semiconductor pillar is made to pierce the stacked body, and a memory cell is formed in an intersection portion of the electrode film and the semiconductor pillar. By processing an end portion of the stacked body into a step-wise shape, providing a step per electrode film, and collectively forming a contact from above, each electrode film is led to a peripheral circuit. However, if the number of steps of the electrode film is increased, a height of the contact is different per electrode film, and it is difficult to accurately form a connection portion of the contact and the electrode film.

### BRIEF DESCRIPTION OF THE DRAWINGS

FIG. 1A and FIG. 1B are cross-sectional views showing a semiconductor memory device according to a first embodiment;

FIG. 2A to FIG. 10B are cross-sectional views of processes showing a method for manufacturing the semiconductor memory device according to the first embodiment;

FIGS. 11A and 11B are cross-sectional views showing a semiconductor memory device according to a second embodiment;

FIGS. 12A and 12B, and FIGS. 13A and 13B are cross-sectional views of processes showing a method for manufacturing the semiconductor memory device according to the second embodiment;

FIGS. 14A and 14B are cross-sectional views showing a semiconductor memory device according to a third embodiment; and

FIGS. 15A and 15B, and FIGS. 16A and 16B are cross-sectional views of processes showing a method for manufacturing the semiconductor memory device according to the third embodiment.

### DETAILED DESCRIPTION

According to one embodiment, a semiconductor memory device includes a multilayer body, a semiconductor pillar, a memory film, an interlayer insulating film and a contact. The multilayer body includes a first insulating film, a first electrode film, a second insulating film, and a second electrode film. There are stacked in this order in the multilayer body. An end portion of the first electrode film extends outside a region directly under the second electrode film in an end portion of the multilayer body. The semiconductor pillar pierces the first electrode film and the second electrode film. The memory film is provided between the first electrode film and the semiconductor pillar and between the second electrode film and the semiconductor pillar. The memory film is capable of storing a charge. The interlayer insulating film is provided on the end portion of the multilayer body. The contact pierces the interlayer insulating film. The contact is connected to the end portion of the first electrode film. A first portion connected to the contact of the first electrode film includes a metal or a metal nitride. A second portion surrounding the memory film of the first electrode film includes silicon. Composition of the second portion is different from composition of the first portion.

According to another embodiment, a method for manufacturing a semiconductor memory device includes forming a multilayer body by stacking a first insulating film, a first electrode film including silicon, a second insulating film, a second electrode film including silicon, and a third insulating film in this order. The method includes forming a hole piercing the third insulating film, the second electrode film, the second insulating film, the first electrode film, and the first insulating film in the multilayer body. The method includes forming a memory film capable of storing a charge on an inner face of the hole. The method includes forming a semiconductor pillar on a side surface of the memory film. The method includes removing a portion of the second electrode directly above an end portion of the first electrode film, and exposing an end face of the second electrode film and an end face of the first electrode film by selectively removing an end portion of the multilayer body. The method includes forming a first concave portion between the first insulating film and the second insulating film in the end portion of the multilayer body, and forming a second concave portion between the second insulating film and the third insulating film in the end portion of the multilayer body by edging back an exposed face of the first electrode film and an exposed face of the second electrode film with etching. The method includes forming a conductive film including a metal or a metal nitride so as to cover the end portion of the multilayer body, to enter the first concave portion and the second concave portion, and to be in contact with the first electrode film and the second electrode film. The method includes dividing the conductive film into a portion connected to the first electrode film and a portion connected to the second electrode film by selectively removing the conductive film. The method includes forming an interlayer insulating film on the end portion of the multilayer body. The method includes forming a contact piercing the interlayer insulating film, and the contact reaching a portion connected to the first electrode film in the conductive film.

### First Embodiment

First, a first embodiment will be described.

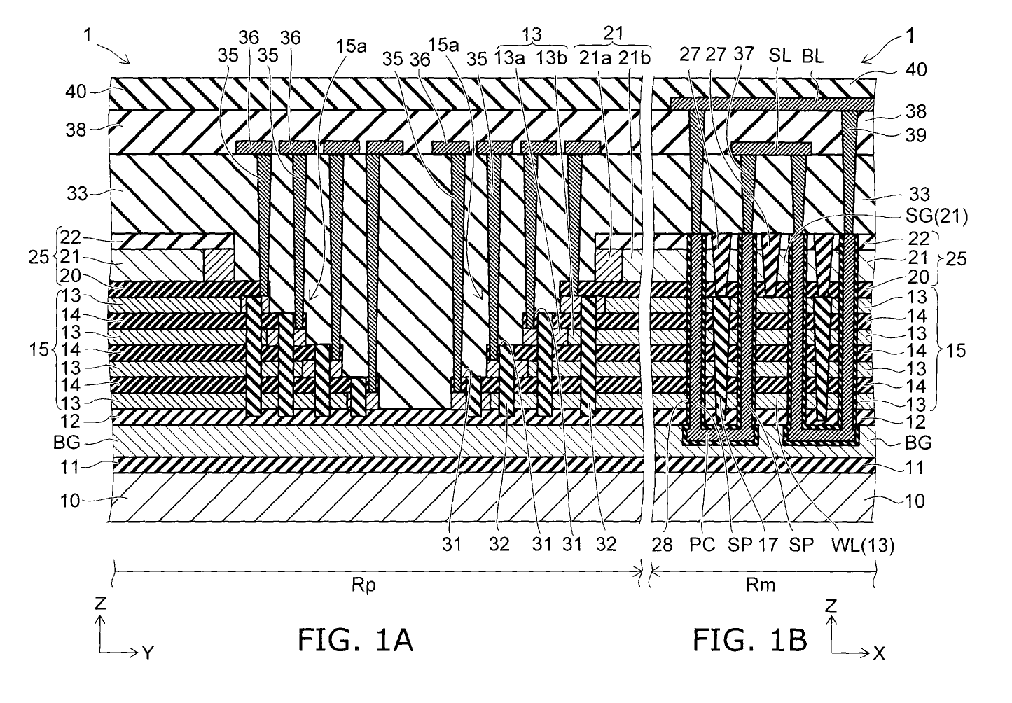

FIG. 1A and FIG. 1B are cross-sectional views showing a semiconductor memory device according to the first embodiment.

The semiconductor memory device according to the first embodiment, is a stacked type nonvolatile semiconductor memory device.

As shown in FIG. 1A and FIG. 1B, in a semiconductor memory device 1 according to the first embodiment, a silicon substrate 10 is provided. Moreover, in the semiconductor memory device 1, a memory cell region Rm where memory cells are arrayed, and a wiring lead-out region Rp where a word line of the memory cell is led, are set.

Hereinafter, in the specification, for convenience of description, an XYZ rectangular coordinate system is adopted. Two directions, which are parallel to an upper face of the silicon substrate 10 and are orthogonal to each other, are assumed to be an “X-direction”, and a “Y-direction”. A direction which is perpendicular to the upper face of the silicon substrate 10, that is, a vertical direction is assumed to be a “Z-direction”. The wiring lead-out region Rp is disposed on both sides of the Y-direction, when seen from the memory cell region Rm.

On the silicon substrate 10, for example, an insulating film 11 which is made of a silicon oxide is provided, and a back gate electrode BG is provided thereon. A shape of the back gate electrode BG is a flat plate shape, and the back gate electrode BG is formed of silicon (Si) including, for example, boron (B). Within an upper layer portion of the back gate electrode BG, a pipe connector PC of almost a rectangular parallel-piped, where the X-direction is assumed to be a longitudinal direction, is provided. On the back gate electrode BG, for example, a stopper film 12 which is made of a silicon nitride is provided.

On the stopper film 12, a plurality of sheets of control gate electrode films 13, and a plurality of sheets of insulating films 14 are alternately stacked, and thus, a stacked body (multilayer body) 15 is formed. Within the stacked body 15, an insulating member 17, which widens in a YZ-flat surface, is provided. The insulating member 17 is formed of an insulating material such as silicon nitride or silicon oxide. The insulating member 17 goes through a directly above region of a center portion of the pipe connector PC in the X-direction. By the insulating member 17, each control gate electrode film 13 is divided into a plurality of band-shaped portions WL which are extended in the Y-direction. That is, the plurality of band-shaped portions WL are respectively extended in the Y-direction, and are arrayed to be mutually distal along the X-direction and the Z-direction. Each band-shaped portion WL functions as a word line.

On the stacked body 15, for example, a stopper film 20 that is made of silicon nitride is provided. On the stopper film 20, a selection gate electrode film 21 that is made of polysilicon to which impurities are added is provided, and on the selection gate electrode film 21, for example, an insulating film 22 which is made of silicon oxide is provided. By the stopper film 20, the selection gate electrode film 21 and the insulating film 22, an upper stacked body 25 is formed.

Within the upper stacked body 25, an insulating member 27 widening in the YZ-flat surface, is provided. The insulating member 27 is formed of an insulating material such as the silicon nitride or the silicon oxide. The insulating member 27 is disposed in the directly above region of the insulating member 17, and a region therebetween. Hence, in the X-direction, an array period of the insulating member 27 is a half of an array period of the insulating member 17. By the insulating member 27, the selection gate electrode film 21 is divided into a plurality of band-shaped portions SG which are extended in the Y-direction. Each band-shaped portion SG functions as a selection gate line.

In the memory cell region Rm, inside the stacked body 15 and the upper stacked body 25, silicon pillars SP which are extended in the Z-direction are plurally provided. Each silicon pillar SP pierces the control gate electrode film 13, the insulating film 14, the stopper film 20, the selection gate electrode film 21, and the insulating film 22. For example, the plural silicon pillars SP are arrayed in a matrix form along the X-direction and the Y-direction. Lower ends of two silicon pillars SP, which are adjacent to each other in the X-direction, are connected to both end portions of the pipe connector PC. The silicon pillar SP and the pipe connector PC are integrally formed of a semiconductor material, for example, silicon (Si). Furthermore, the plural silicon pillars SP may be arrayed in a zigzag shape.

On a surface of a structure body which is made of two silicon pillars SP and one pipe connector PC, a memory film 28 which is capable of storing a charge is provided. That is, the memory film 28 is disposed between the silicon pillar SP and the control gate electrode film 13, and between the silicon pillar SP and the selection gate electrode film 21. In the memory film 28, a tunnel insulating layer, a charge storage layer, and a block insulating layer (none of which are shown) are stacked in order from the silicon pillar SP side. The tunnel insulating layer typically has insulating properties. However, if a desired voltage, which is within a range of a drive voltage of the semiconductor memory device 1, is applied, the tunnel insulating layer is a layer where a FN tunnel current flows. The charge storage layer is a layer which has a capability of storing the charge, and is formed of a material having, for example, a trap site of an electron. The block insulating layer is a layer where the current does not substantially flow even when the voltage within the range of the drive voltage of the semiconductor memory device 1 is applied. Hereby, the memory cell is formed at every intersection portion of the silicon pillar SP and the control gate electrode film 13.

On the other hand, in the wiring lead-out region Rp, an end portion 15a of the stacked body 15 in the Y-direction is processed into a step-wise shape, and a step 31 is formed at every control gate electrode film 13. The step 31 is an upper face of the control gate electrode film 13 or the insulating film 14, and the step 31 is a region where other control gate electrode films 13, other insulating films 14 and the upper stacked body 25 are not disposed in the directly above region thereof. Hereby, the end portion of a certain insulating film 14 and the control gate electrode film 13 which is disposed on one layer is extended to the outside of a directly under region of the insulating film 14 and the control gate electrode film 13 which are disposed upwards therefrom. That is, all of the control gate electrode films 13 configuring each step 31 are disposed in the directly under region of the insulating films 14 configuring the same steps 31. Moreover, the end portions of the control gate electrode film 13 of the uppermost step and the stopper film 20, are extended to the outside of the directly under region of the selection gate electrode film 21. In the wiring lead-out region Rp, two end portions 15a are formed so as to be opposed to each other, and are formed into one valley. The control gate electrode films 13 of the same steps, which are opposed by sandwiching the valley, may be integrated on a back side or a front side of paper in FIG. 1A.

Moreover, within the end portion 15a of the stacked body 15, a support 32 which is made of the insulating material is provided. A shape of the support 32 is a column shape which is extended in Z-direction, and a lower end thereof is positioned within the stopper film 12, and an upper end thereof protrudes from the step 31. Therefore, the support 32 is in contact with all of the control gate electrode films 13 and the insulating films 14 which are pierced.

On the stopper film 12, so as to cover the stacked body 15 and the upper stacked body 25, for example, an interlayer insulating film 33 which is made of the silicon oxide is provided. Within a portion which is disposed in the directly above region of the end portion 15a of the stack body 15 in the interlayer insulating film 33, plural contacts 35, which are extended in the Z-direction and pierce the interlayer insulating film 33, are provided. A lower end of each contact 35 is in contact with the upper face of the control gate electrode film 13, in the step 31. The contact 35 is formed of a metal, for example, tungsten (W).

An end portion 13a of the control gate electrode film 13 is formed of a material of one type or more that is selected from a group which is made of a conductive material including a metal or a metal nitride, for example, tungsten, titanium (Ti), a tungsten nitride (WN) and a titanium nitride (TiN). For example, the end portion 13a includes tungsten. The end portion 13a of the control gate electrode film 13 is disposed in the end portion 15a of the stacked body 15, and is made of a portion where other control gate electrode films 13 are not disposed in the directly above region thereof, and a portion in the vicinity thereof. The end portion 13a is in contact with the contact 35.

On the other hand, a composition of a main body portion 13b except for the end portion 13a in the control gate electrode film 13 is different from composition of the end portion 13a. The main body portion 13b is formed of a conductive material including silicon, for example, silicon including boron. The main body portion 13b of the control gate electrode film 13 is a portion which is pierced by the silicon pillar SP, and is a portion which surrounds the memory film 28.

Similarly, an end portion 21a of the selection gate electrode film 21 in the Y-direction is formed of the conductive material including the metal or the metal nitride, in the same manner as the end portion 13a. Moreover, a main body portion 21b except for the end portion 21a in the selection gate electrode film 21 is formed of the conductive material including silicon, for example, silicon including boron.

On the interlayer insulating film 33, a source line SL which is extended in the Y-direction, and a word lead-out line 36 which is extended in the X-direction, are provided. A plug 37 is provided within the interlayer insulating film 33, and the source line SL is two silicon pillars SP which are adjacent to each other along the X-direction through the plug 37, and is connected to the silicon pillar SP which is not connected to each other by the pipe connector PC. The word lead-out line 36 is connected to an upper end of the contact 35.

On the interlayer insulating film 33, an interlayer insulating film 38 is provided so as to cover the source line SL and the word lead-out line 36. On the interlayer insulating film 38, a bit line BL which is extended in the X-direction is provided. Moreover, a plug 39 is provided within the interlayer insulating films 33 and 38. The bit line BL is connected to the silicon pillar SP which is not connected to the source line SL through the plug 39. On the interlayer insulating film 38, an interlayer insulating film 40 is provided so as to cover the bit line BL.

Next, a method for manufacturing a semiconductor memory device according to the first embodiment, will be described.

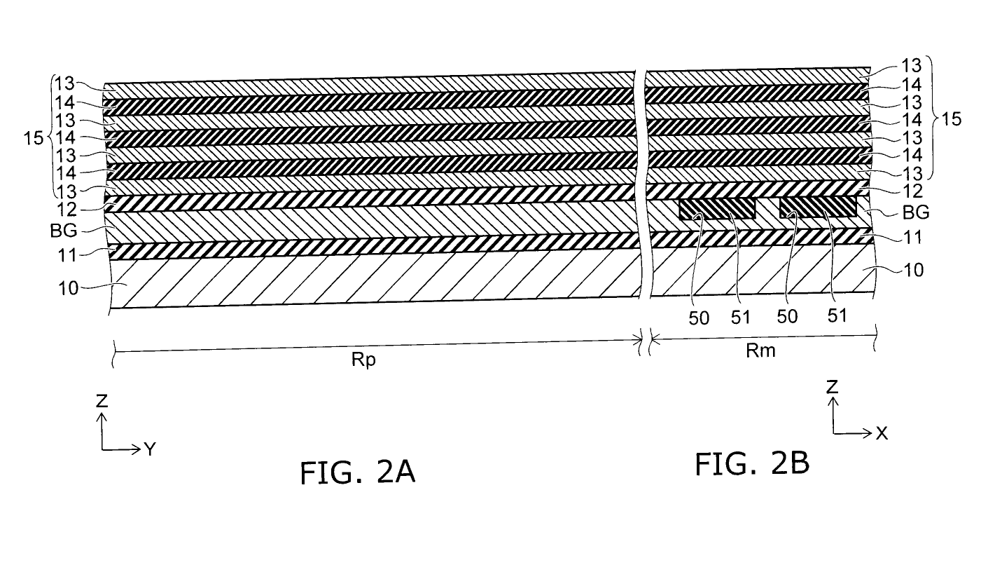

FIG. 2A to FIG. 10B are cross-sectional views of processes showing the method for manufacturing a semiconductor memory device according to the first embodiment.

First, as shown in FIGS. 2A and 2B, on the silicon substrate 10, for example, the insulating film 11 which is made of the silicon oxide is formed. Next, for example, a back gate electrode film BG which is made of polysilicon including boron is formed. Next, on the upper portion of the back gate electrode film BG, a concave portion 50 of almost the rectangular parallel-piped, where the X-direction is assumed to be the longitudinal direction, is formed, and for example, a sacrifice member 51 which is made of the silicon nitride is embedded in the concave portion 50. Subsequently, on the back gate electrode film BG, for example, the stopper film 12 which is made of the silicon nitride is formed.

Next, the stacked body 15 is formed by alternately stacking the control gate electrode film 13 and the insulating film 14. At this time, the control gate electrode film 13 is formed of the conductive material including silicon, for example, polysilicon to which boron is added. The insulating film 14 is formed of the insulating material, for example, the silicon oxide.

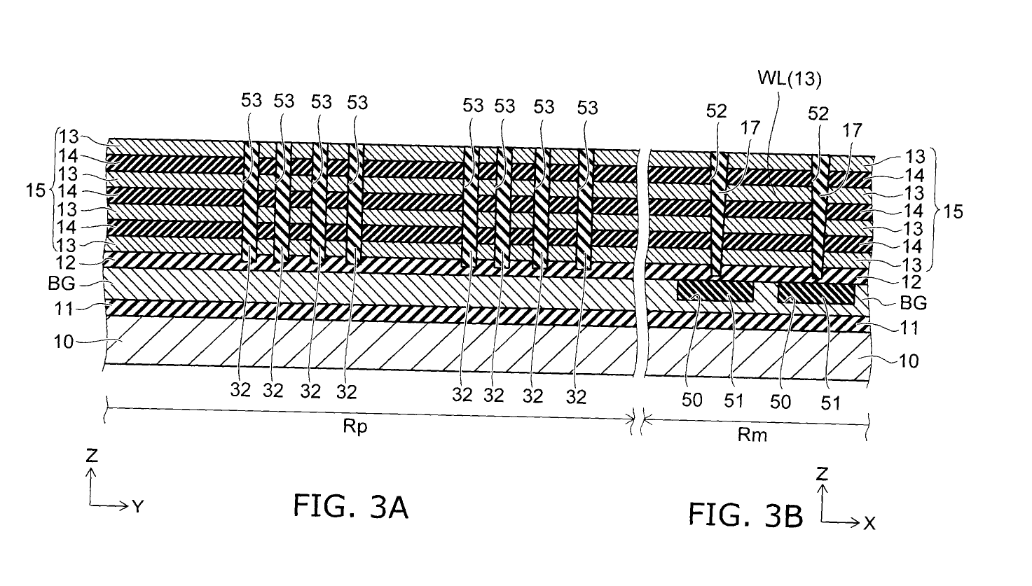

Subsequently, as shown in FIGS. 3A and 3B, a mask pattern (not shown) is formed on the stacked body 15, and the stopper film 12 is made as a stopper, and for example, anisotropic etching such as reactive ion etching (RIE), is performed. Hereby, in the memory cell region Rm, a slit 52 widening in the YZ-flat surface, is formed, so as to go through the directly above region of a center portion of the sacrifice member 51 in the X-direction. On the other hand, in the wiring lead-out region Rp, a hole for support 53 which is extended in the Z-direction is formed. The slit 52 and the hole for support 53 reach the stopper film 12, but do not pierce the stopper film 12. By the slit 52, each control gate electrode film 13 is divided into the plurality of band-shaped portions WL which are extended in the Y-direction.

Next, for example, by chemical vapor deposition (CVD), the insulating material such as the silicon nitride or the silicon oxide is deposited, and is embedded in the slit 52 and the hole for support 53. Next, chemical mechanical polishing (CMP) is performed, and the insulating material which is deposited on an upper face of the stacked body 15 is removed. Hereby, the insulating member 17 is formed within the slit 52, and the support 32 is formed within the hole for support 53. The insulating member 17 and the support 32 pierce all of the control gate electrode films 13 and the insulating films 14 of the stacked body 15, and reach the stopper film 12.

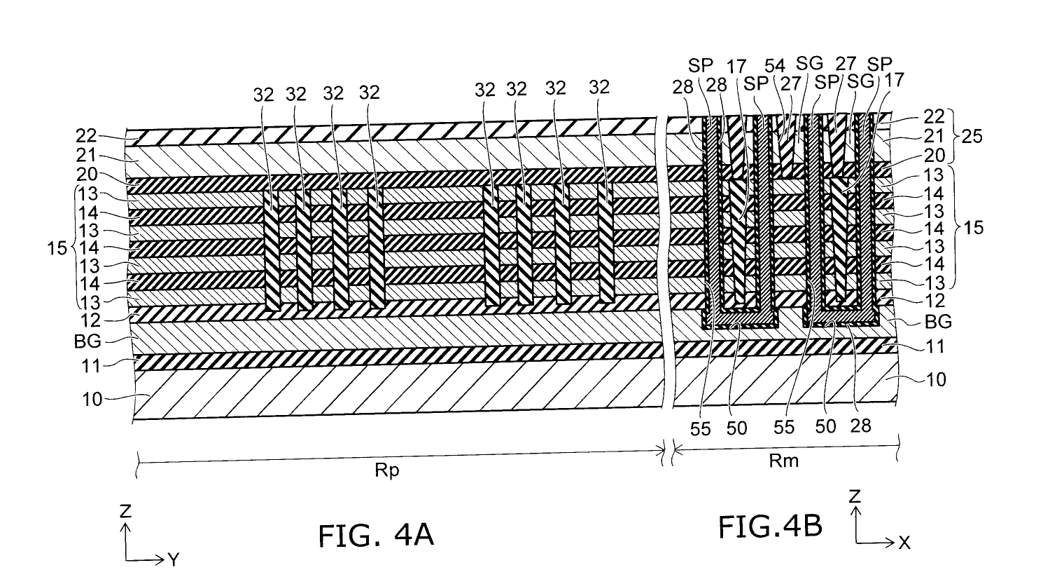

Subsequently, as shown in FIGS. 4A and 4B, on the stacked body 15, the stopper film 20 which is made of, for example, the silicon nitride is formed, and the selection gate electrode film 21 which is made of, for example, silicon including boron is formed, and the insulating film 22 which is made of, for example, the silicon oxide is formed. Hereby, the upper stacked body 25 is formed.

Next, the mask pattern (not shown) is formed on the upper stacked body 25, and the stopper film 20 is made as a stopper, and anisotropic etching such as RIE is performed. Hereby, a slit 54 which is extended in the Y-direction is formed in the directly above region of the insulating member 17, and the directly above region of an intermediate position of the insulating member 17 which is adjacent thereto. By the slit 54, each selection gate electrode film 21 is divided into the plurality of band-shaped portions SG which are extended in the Y-direction. Next, by embedding the insulating material such as the silicon nitride or the silicon oxide in the slit 54, the insulating member 27 is formed. Thereafter, the mask pattern is removed.

Subsequently, another mask pattern (not shown) is formed on the upper stacked body 25, and for example, the anisotropic etching such as the RIE is performed. Hereby, in the memory cell region Rm, a memory hole 55 is formed within the upper stacked body 25 and the stacked body 15. The memory hole 55 pierces the insulating film 22, the selection gate electrode film 21, the stopper film 20, the insulating film 14, the control gate electrode film 13, and the stopper film 12, and reaches both end portions of the concave portion 50 in the X-direction. Next, by performing wet etching through the memory hole 55, the sacrifice member 51 (see FIG. 3B) is removed. Subsequently, on inner faces of the memory hole 55 and the concave portion 50, by forming the block insulating layer, the charge storage layer, and the tunnel insulating layer in order, the memory film 28 is formed. Next, for example, by the CVD, silicon forming a channel layer is deposited on the memory film 28. Hereby, the pipe connector PC is formed within the concave portion 50, and the silicon pillar SP is formed within the memory hole 55.

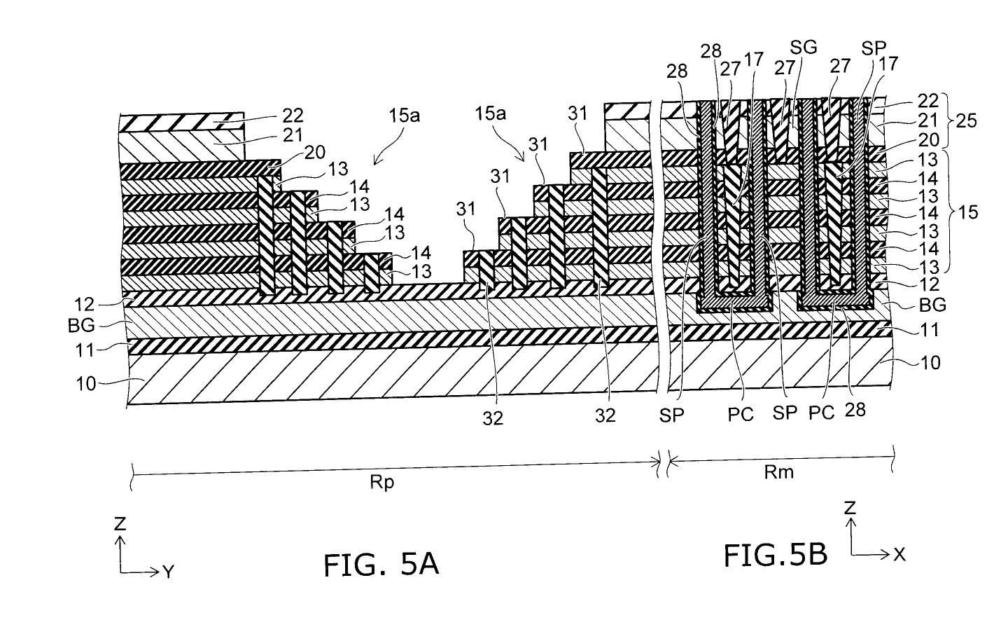

Subsequently, as shown in FIGS. 5A and 5B, the end portion of the upper stacked body 25 is removed, and the end portion 15a of the stacked body 15 is processed into the step-wise shape. For example, a thick block-shaped resist film (not shown) is formed on the upper stacked body 25, and an etching process of making the resist film as a mask, and a slimming process of making a size be slightly smaller by ashing the resist film, are alternately repeated. Hereby, the end portion 15a of the stacked body 15 is selectively removed, and among the insulating film 14 of each step and the control gate electrode film 13 on one layer under the insulating film 14, a portion, which is disposed in the directly above region of the end portions of the insulating film 14 and the control gate electrode film 13 of lower layers therefrom, is removed. As a result, the step 31 is formed per pair of the control gate electrode film 13 and the insulating film 14.

In each step 31, the insulating film 14 is disposed above the control gate electrode film 13. Moreover, an end face of the control gate electrode film 13 of each step is exposed. Still more, in each step 31, the upper end of the support 32 is exposed on an upper face of the insulating film 14. The control gate electrode film 13 of the uppermost step is covered by the stopper film 20, and the selection gate electrode film 21 and the insulating film 22 are removed from the end portions of the control gate electrode film 13 of the uppermost step and the stopper film 20.

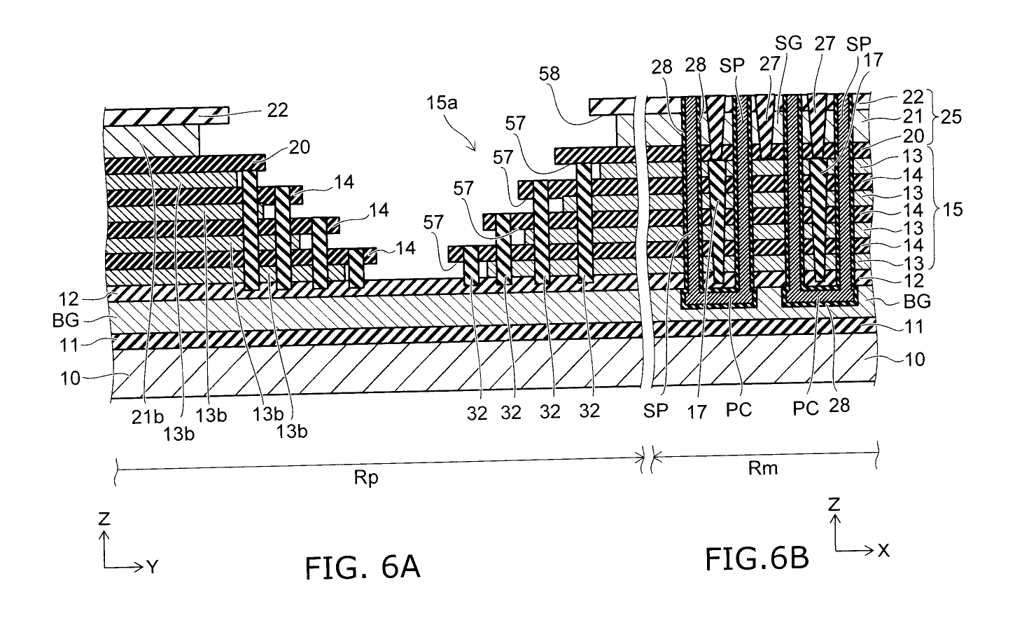

Next, as shown in FIGS. 6A and 6B, isotropic etching is performed under such conditions so that an etching rate of silicon is higher than an etching rate of the silicon oxide and the silicon nitride. For example, the wet etching is performed using TMY (choline aqueous solution) as an etching solution. Hereby, in the end portion 15a of the stacked body 15, the exposed portions of the control gate electrode film 13 and the selection gate electrode film 21 are removed, and the respective end faces thereof are moved back.

As a result, in the end portion 15a, a concave portion 57 is formed between the stopper film 12 and the insulating film 14 of the lowermost step, and between two sheets of the insulating films 14 which are adjacent to each other in the Z-direction, and between the insulating film 14 of the uppermost step and the stopper film 20. Moreover, in the end portion of the upper stacked body 25, a concave portion 58 is formed between the stopper film 20 and the insulating film 22. At this time, the support 32 is disposed within the concave portion 57, and the support 32 supports the control gate electrode film 13. Hereby, it can be suppressed that the concave portion 57 is broken by surface tension or the like at the time of removing the etching solution. Furthermore, a left-behind portion of the control gate electrode film 13 becomes the main body portion 13b, and a left-behind portion of the selection gate electrode film 21 becomes the main body portion 21b.

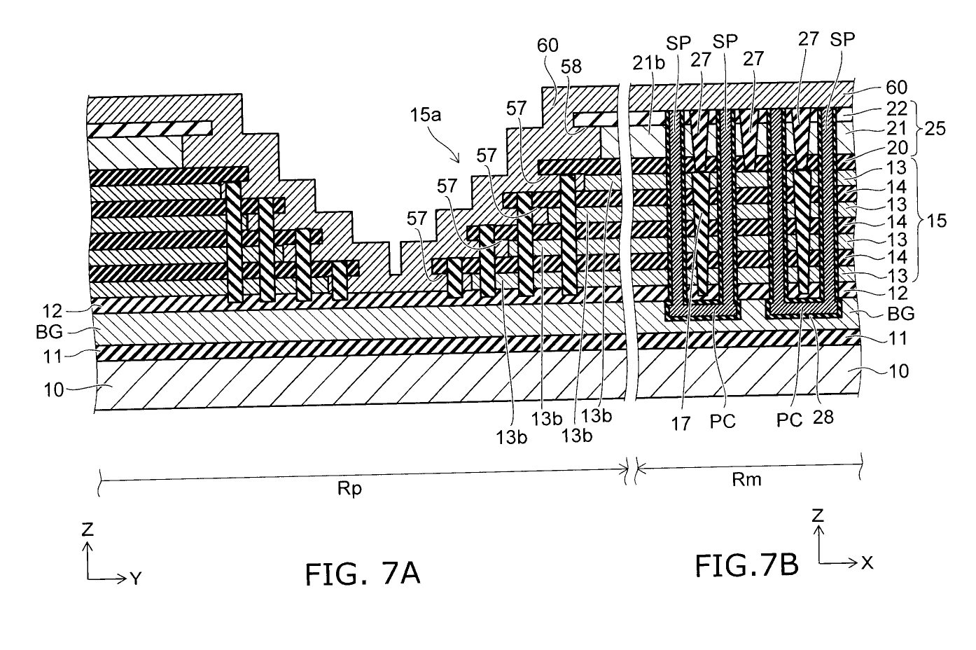

Next, as shown in FIGS. 7A and 7B, a conductive film 60 including the metal or the metal nitride, is deposited all over the surface. For example, the conductive film 60 is formed of the material of one sort or more that is selected from the group which is made of tungsten, titanium, tungsten nitride and titanium nitride. For example, the conductive film 60 includes tungsten. It is favorable that the conductive film 60 is formed of the conductive material which is favorable in embedding properties. The conductive film 60 also covers the end portion 15a of the stacked body 15, enters the inside of the concave portions 57 and 58, is in contact with the main body portion 13b of the control gate electrode film 13 within the concave portion 57, and is in contact with the main body portion 21b of the selection gate electrode film 21 within the concave portion 58.

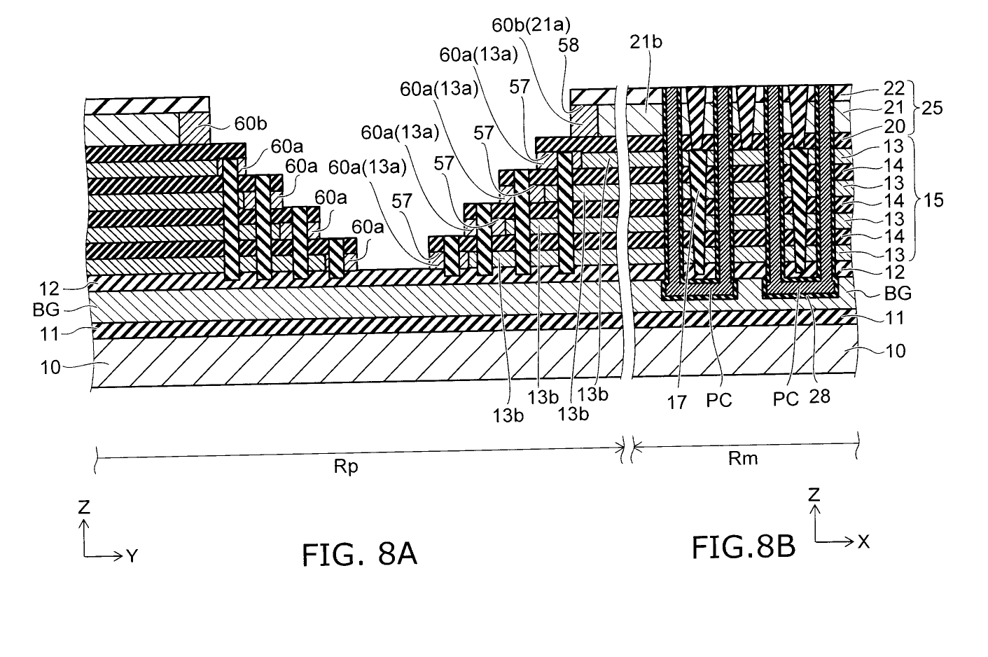

Next, as shown in FIGS. 8A and 8B, the anisotropic etching such as the RIE is performed all over the surface. Hereby, the conductive film 60 is removed from the upper face side. Therefore, among an upper face of the stopper film 12, the upper face of the insulating film 14, an upper face of the stopper film 20, and an upper face of the insulating film 22, a region where other insulating films 14, the stopper film 20 and the insulating film 22 are not disposed in the directly above region thereof is exposed. Hereby, among the conductive film 60, portions, which are deposited on the upper face of the stopper film 12, on the upper face of the insulating film 14, on the upper face of the stopper film 20, and on the upper face of the insulating film 22, are removed, and are also removed from an end face of the insulating film 14, an end face of the stopper film 20, and an end face of the insulating film 22. On the other hand, among the conductive film 60, a portion 60a which is embedded in the concave portion 57 and is connected to the control gate electrode film 13 are left, and a portion 60b which is embedded in the concave portion 58 and is connected to the selection gate electrode film 21 are left. As a result, a plurality of portions 60a and 60b of the conductive film 60 are divided from each other. The portion 60a of the conductive film 60 becomes the end portion 13a of the control gate electrode film 13, and the portion 60b becomes the end portion 21a of the selection gate electrode film 21.

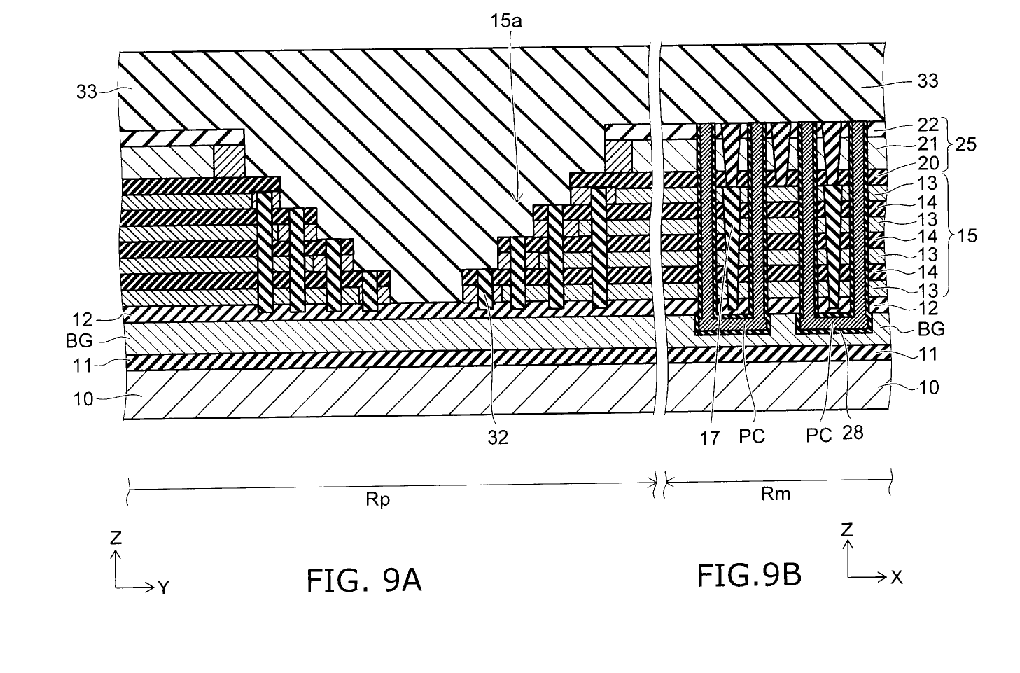

Subsequently, as shown in FIGS. 9A and 9B, for example, by the CVD, the interlayer insulating film 33 which is made of, for example, the silicon oxide is formed on the stopper film 12, so as to cover the stacked body 15 and the upper stacked body 25. For example, a silicon oxide film is formed by high density plasma chemical vapor deposition (HDP-CVD), or a non doped silicate glass (NSG) film is formed by the CVD, or a silicon oxide film is formed using polysilazane. Hereby, a whole of the end portion 15a of the stacked body 15 is embedded by the interlayer insulating film 33. Next, by performing CMP, an upper face of the interlayer insulating film 33 is flattened.

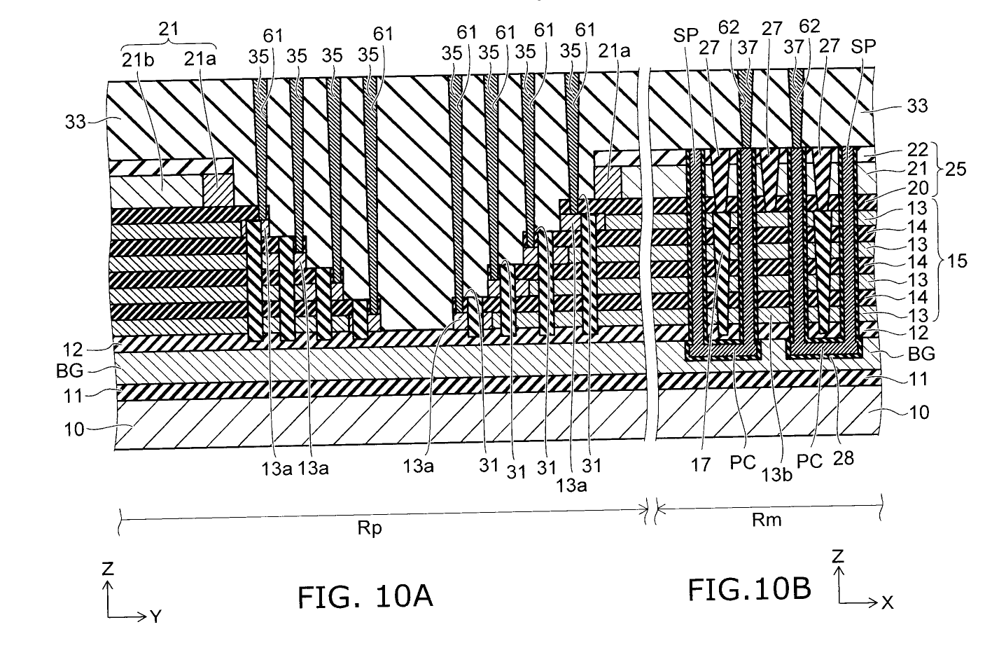

Next, as shown in FIGS. 10A and 10B, by performing the anisotropic etching such as the RIE, a contact hole 61 is formed in the directly above region of the step 31 in the interlayer insulating film 33. The contact hole 61 is extended in the Z-direction, pierces the interlayer insulating film 33 and insulating film 14 of one layer, and reaches the end portion 13a of the control gate electrode film 13. At this time, since the end portion 13a is formed of the metal such as tungsten or the metal nitride, the contact hole 61 does not pierce the end portion 13a. In such the process, a hole 62 is formed in the directly above region of a portion of the silicon pillar SP in the interlayer insulating film 33, so as to reach the silicon pillar SP.

Next, all over the surface, for example, a barrier metal film (not shown) which includes the titanium nitride (TiN) is formed, and for example, a metal film which is made of tungsten (W) is formed. The metal film enters the contact hole 61, and is in contact with the end portion 13a of the control gate electrode film 13. Along therewith, the metal film enters the hole 62, and is in contact with an upper end of the silicon pillar SP. Next, the CMP is performed with respect to an upper face of the metal film. Hereby, the portions entering the contact hole 61 and the hole 62 in the metal film are left, and the portion which is deposited on the upper face of the interlayer insulating film 33 is removed. As a result, the contact 35 is formed within the contact hole 61, and the plug 37 is formed within the hole 62.

Subsequently, as shown in FIGS. 1A and 1B, the source line SL and the word lead-out line 36 are formed on the interlayer insulating film 33. The source line SL is formed at a position which is connected to an upper end of the plug 37, and the word lead-out line 36 is formed at a position which is connected to an upper end of the contact 35. Next, on the interlayer insulating film 33, the interlayer insulating film 38 is formed so as to cover the source line SL and the word lead-out line 36. Next, the plug 39 is formed within the interlayer insulating film 38 and the interlayer insulating film 33, and is connected to the silicon pillar SP which is not connected to the plug 37. Next, the bit line BL is formed on the interlayer insulating film 38. The bit line BL is formed at a position which is connected to an upper end of the plug 39. Subsequently, on the interlayer insulating film 38, the interlayer insulating film 40 is formed so as to cover the bit line BL. In this manner, the semiconductor memory device 1 according to the first embodiment is manufactured.

Next, effects of the first embodiment will be described.

In the first embodiment, in the process shown in FIGS. 6A and 6B, the concave portion 57 is formed by removing the end portion of the control gate electrode film 13 from the end portion 15a of the stacked body 15, and in the process shown in FIGS. 7A and 7B, the conductive film 60 is deposited all over the surface. In the process shown in FIGS. 8A and 8B, the conductive film 60 is divided per portion which is connected to the control gate electrode film 13, and is made as the end portion 13a of the control gate electrode film 13. Hereby, in the process shown in FIGS. 10A and 10B, since the end portion 13a which is made of the metal or the metal nitride, becomes an etching stopper at the time of forming the contact hole 61 in the interlayer insulating film 33 by the etching, it is possible to prevent the contact hole 61 from breaking through the control gate electrode film 13. Accordingly, the contact 35 reaches the control gate electrode film 13 of the lower layer by breaking through the control gate electrode film 13, and thereby, it is possible to prevent the control gate electrode films 13 from being short-circuited. As a result, it is possible to manufacture a semiconductor memory device of which reliability is high.

Moreover, in the first embodiment, since the control gate electrode film 13 is used as an etching stopper, there is no need to form a general-purpose etching stopper film on the end portion 15a of the stacked body 15. Hereby, it is possible to shorten a length of a terrace 31 in the Y-direction as much as a film thickness of the etching stopper film, in comparison with a case of forming the general-purpose etching stopper film.

Furthermore, according to the first embodiment, the end portion 13a of the control gate electrode film 13 and the end portion 21a of the selection gate electrode film 21 are formed of the metal or the metal nitride, and thereby, it is possible to reduce electric resistance of the control gate electrode film 13 and the selection gate electrode film 21.

### Second Embodiment

Next, a second embodiment will be described.

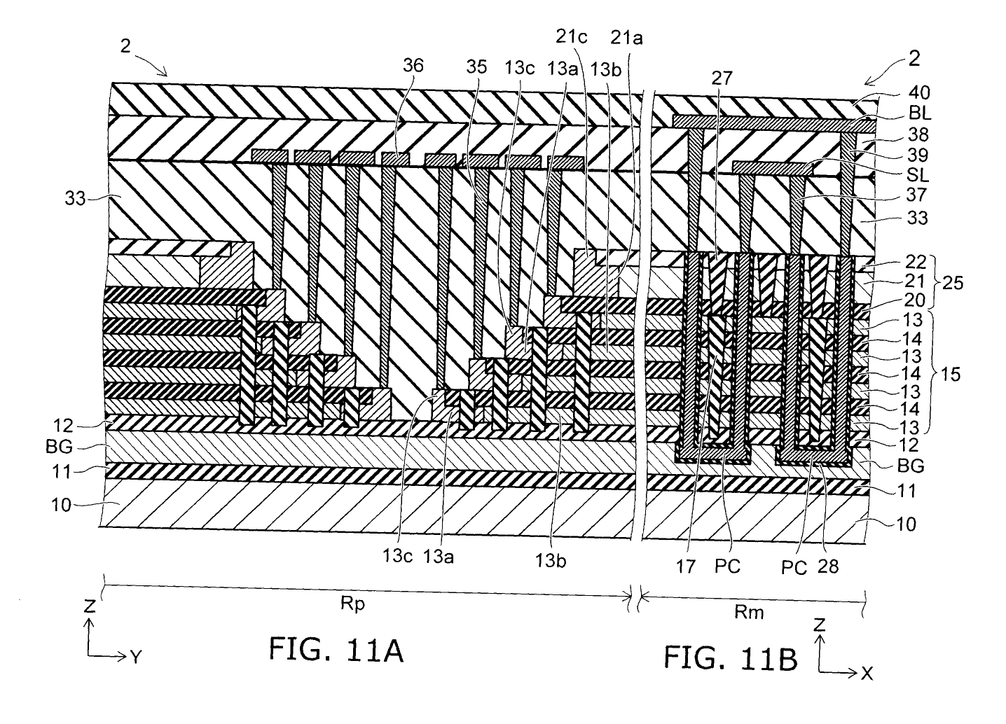

FIGS. 11A and 11B are cross-sectional views showing a semiconductor memory device according to the second embodiment.

As shown in FIGS. 11A and 11B, in a semiconductor memory device 2 according to the second embodiment, a tip portion 13c of the end portion 13a of each control gate electrode film 13 is extended up to the outside of the directly under region of the insulating film 14 on one layer above the control gate electrode film 13. Moreover, the tip portion 13c is thicker than the portion except for the tip portion 13c in the control gate electrode film 13, that is, the portion which is disposed in the directly under region of the insulating film 14 on one layer above the control gate electrode film 13. Hereby, the tip portion 13c covers at least a portion of the end face of the insulating film 14 on one layer. Therefore, the contact 35 is connected to an upper face of the tip portion 13c.

Similarly, a tip portion 21c of the end portion 21a of the selection gate electrode film 21 is extended up to the outside of the directly under region of the insulating film 22. The tip portion 21c is thicker than the portion except for the tip portion 21c in the selection gate electrode film 21, that is, the portion which is disposed in the directly under region of the insulating film 22. Hereby, the tip portion 21c covers at least a portion of the end face of the insulating film 22. A configuration of the second embodiment other than the above point is the same as the first embodiment described above.

Next, a method for manufacturing a semiconductor memory device according to the second embodiment, will be described.

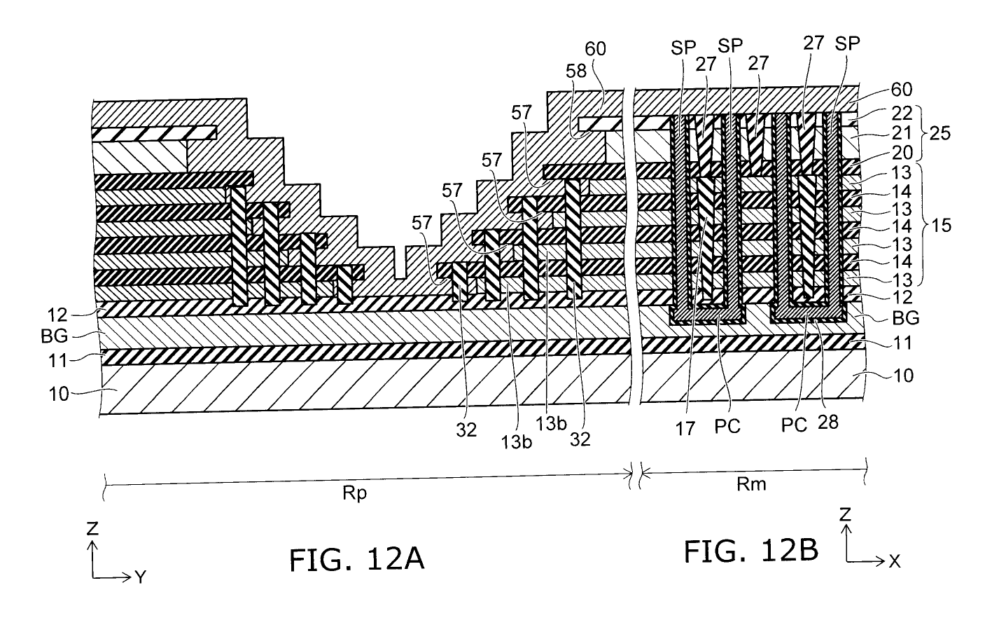

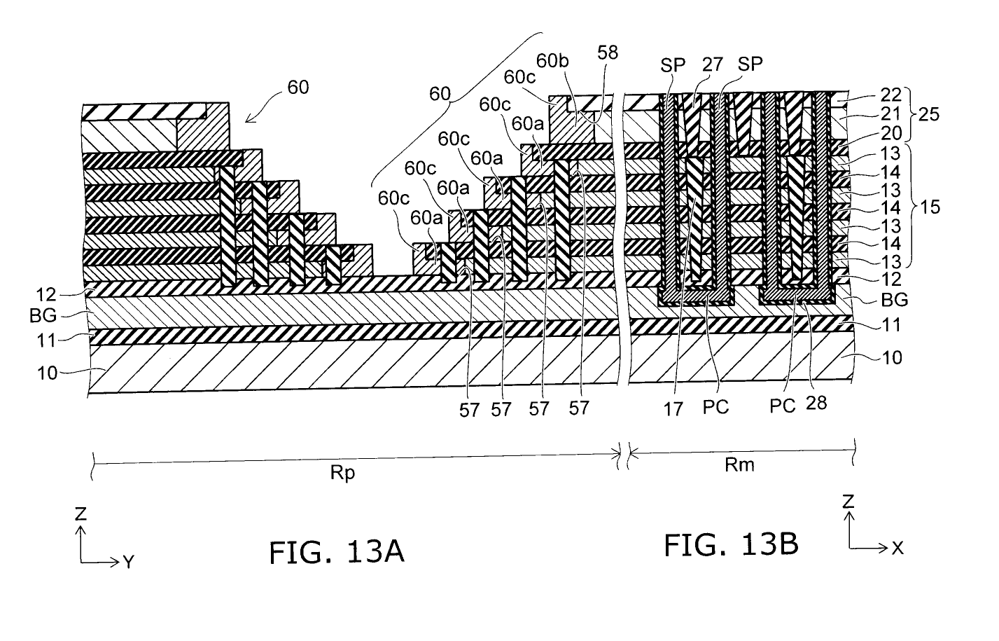

FIGS. 12A and 12B, and FIGS. 13A and 13B are cross-sectional views of the processes showing the method for manufacturing a semiconductor memory device according to the second embodiment.

First, the processes shown in FIGS. 2A and 2B to FIGS. 7A and 7B, are performed. Hereby, as shown in FIGS. 12A and 12B, the end portion 15a of the stacked body 15 is processed into the step-wise shape, and the concave portion 57 is formed between the insulating films 14 which are adjacent to each other in the Z-direction, and the concave portion 58 is formed between the stopper film 20 and the insulating film 22, and an intermediate structure body of which an overall surface is covered by the conductive film 60 is fabricated.

Next, as shown in FIGS. 13A and 13B, the anisotropic etching such as the RIE is performed all over the surface. At this time, the etching is stopped in an early stage in comparison with the first embodiment described above, and at least a portion of the portions which are formed on the end face of the insulating film 14, the end face of the stopper film 20, and the end face of the insulating film 22 in the conductive film 60, is left. Hereby, among the conductive film 60, a portion 60c, which is extended from the directly under region of the insulating film 14 and the insulating film 22, is left by being thicker than the portion 60a which is embedded in the concave portion 57, and the portion 60b which is embedded in the concave portion 58. The portion 60c becomes the tip portion 13c of the control gate electrode film 13, and the tip portion 21c of the selection gate electrode film 21.

However, in order to divide the portion 60a connected to each control gate electrode film 13 and the portion 60b connected to the selection gate electrode film 21 in the conductive film 60 from each other, a portion of the upper face of the insulating film 14 is exposed. In order to reliably prevent a short circuit of the control gate electrode films 13, it may be slightly over-etched, after the upper face of the insulating film 14 is exposed.

Subsequently, the processes shown in FIGS. 9A and 9B, and FIGS. 10A and 10B, are performed. Hereby, the contact 35 is formed within the interlayer insulating film 33. At this time, the contact hole 61 reaches the tip portion 13c. The following processes are the same as the first embodiment described above.

Next, the effects of the second embodiment will be described.

In the second embodiment, the tip portion 13c of the control gate electrode film 13 is formed to be thicker than other portions, in the process shown in FIGS. 13A and 13B. Hereby, at the time of forming the contact hole 61, it is possible to more reliably prevent the contact hole 61 from piercing the control gate electrode film 13. The effects of the second embodiment other than the above point, are the same as the first embodiment described above.

### Third Embodiment

Next, a third embodiment will be described.

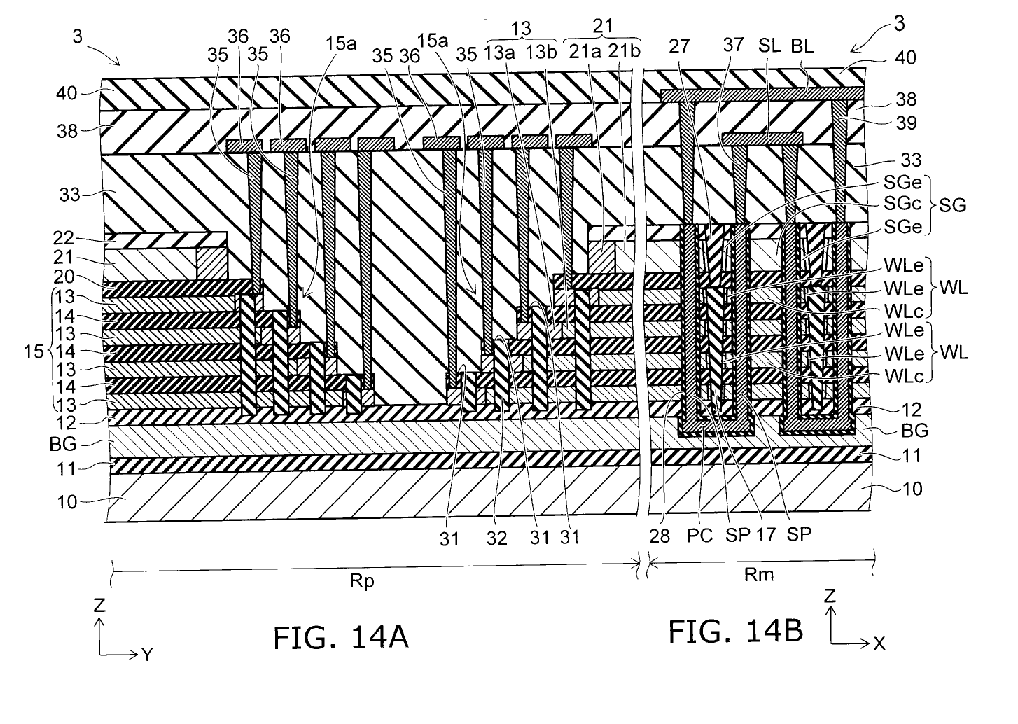

FIGS. 14A and 14B are cross-sectional views showing a semiconductor memory device according to the third embodiment.

As shown in FIGS. 14A and 14B, in a semiconductor memory device 3 according to the third embodiment, both end portions WLe in a width direction (X-direction) of the band-shaped portion WL of the control gate electrode film 13, are formed of the conductive material including the metal, for example, tungsten. On the other hand, a center portion WLc in the width direction of the band-shaped portion WL of the control gate electrode film 13, is formed of the conductive material including silicon, for example, polysilicon to which boron is added.

Similarly, both end portions SGe in the width direction (X-direction) of the band-shaped portion SG of the selection gate electrode film 21 are formed of the conductive material including the metal, for example, tungsten. On the other hand, a center portion SGc in the width direction of the band-shaped portion SG of the selection gate electrode film 21 is formed of the conductive material including silicon, for example, polysilicon to which boron is added. A configuration of the third embodiment other than the above point is the same as the first embodiment described above.

Next, a method for manufacturing a semiconductor memory device according to the third embodiment will be described.

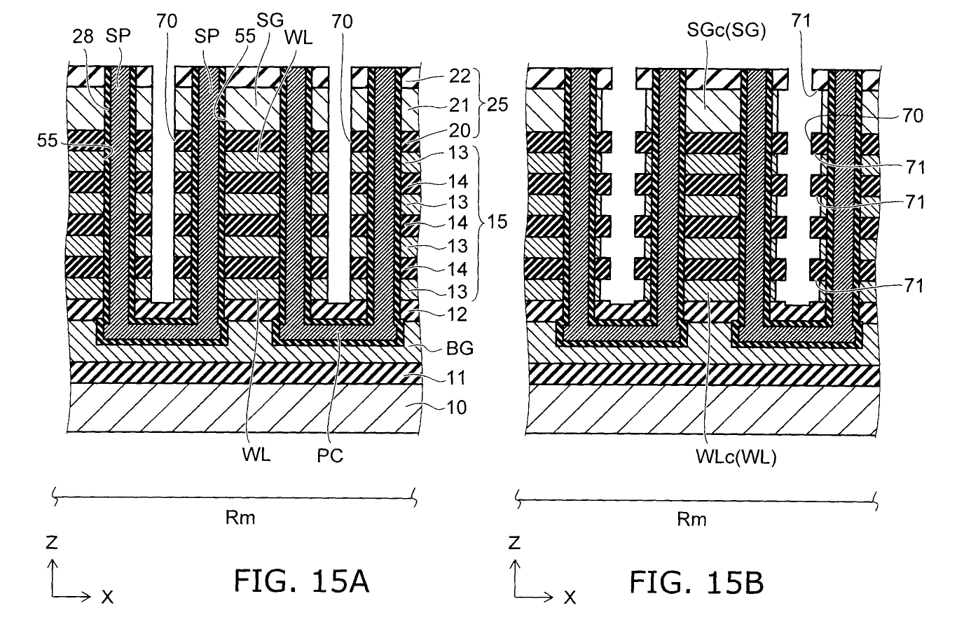

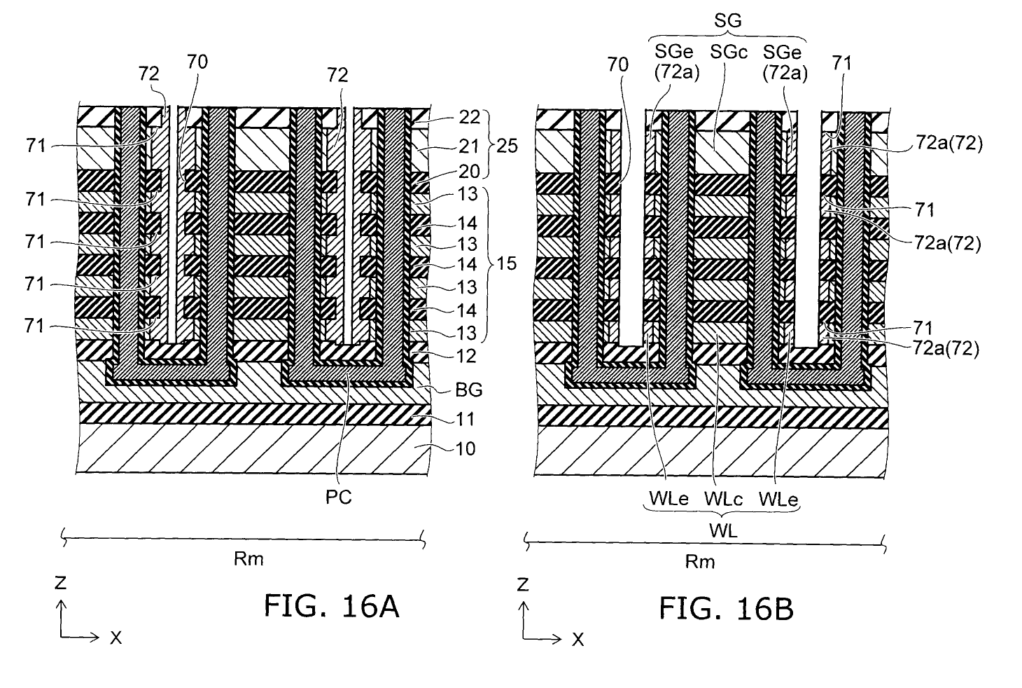

FIGS. 15A and 15B, and FIGS. 16A and 16B are cross-sectional views of the processes showing the method for manufacturing a semiconductor memory device according to the third embodiment.

First, as shown in FIG. 15A, by the same method as the first embodiment described above, the insulating film 11, the back gate electrode film BG, and the stopper film 12 are formed on the silicon substrate 10. Thereon, the control gate electrode film 13 and the insulating film 14 are alternately stacked, and thereby, the stacked body 15 is formed. Next, the stopper film 20, the selection gate electrode film 21, and the insulating film 22 are formed, and thereby, the upper stacked body 25 is formed.

Next, the memory hole 55 is formed in the upper stacked body 25 and the stacked body 15. Next, the memory film 28 and the silicon pillar SP are formed within the memory hole 55. Next, by the anisotropic etching such as the RIE, a slit 70 is formed in the upper stacked body 25 and the stacked body 15. By the slit 70, each control gate electrode film 13 is divided into the plurality of band-shaped portions WL, and the selection gate electrode film 21 is divided into the plurality of band-shaped portions SG.

Subsequently, as shown in FIG. 15B, the isotropic etching such as the wet etching is performed through the slit 70. Hereby, the exposed face of the control gate electrode film 13, and the exposed face of the selection gate electrode film 21 in an inner face of the slit 70, are moved back. As a result, a concave portion 71 is formed between the stopper film 12 and the insulating film 14 of the lowermost step in the inner face of the slit 70, and between the insulating films 14 which are adjacent to each other in the Z-direction, and between the insulating film 14 of the uppermost step and the stopper film 20, and between the stopper film 20 and the insulating film 22. At this time, a left-behind portion in the band-shaped portion WL, becomes the center portion WLc. Moreover, a left-behind portion in the band-shaped portion SG, becomes the center portion SGc.

Next, as shown in FIG. 16A, a metal film 72 is embedded in the slit 70. For example, the metal film 72 includes tungsten. The metal film 72 is also embedded in the concave portion 71, and is in contact with the center portion WLc and the center portion SGc.

Next, as shown in FIG. 16B, by performing the anisotropic etching such as the RIE with respect to the metal film 72, a portion which is disposed on the end face of the insulating film 14, and a portion which is disposed on the end face of the stopper film 20 within the slit 70, are removed, while a portion 72a which is disposed within the concave portion 71 in the metal film 72 is left. Hereby, the portions 72a which are disposed within the concave portion 71 in the metal film 72 are divided. The portion 72a which is bonded to the center portion WLc of the band-shaped portion WL of the control gate electrode film 13 becomes the both end portions WLe of the band-shaped portion WL. Moreover, the portion 72a which is bonded to the center portion SGc of the band-shaped portion SG of the selection gate electrode film 21 becomes the both end portions SGe of the band-shaped portion SG. The manufacturing method of the third embodiment other than the above point is the same as the first embodiment described above.

Subsequently, the effects of the third embodiment will be described.

In the third embodiment, the control gate electrode film 13 and the selection gate electrode film 21 are partially formed of the metal, and thereby, it is possible to reduce the resistance. The effects of the third embodiment other than the above point are the same as the first embodiment described above. Furthermore, in the third embodiment, after the process shown in FIGS. 5A and 5B which is described in the first embodiment, the insulating members 17 and 27 are removed, and thereafter, the process of removing the end portion of the control gate electrode film 13, and the end portion of the selection gate electrode film 21, may be performed. Hereby, it is possible to form the end portion 13a of the control gate electrode film 13, and the end portion 21a of the selection gate electrode film 21 at the same time as the both end portions WLe of the band-shaped portion WL of the control gate electrode film 13, and the both end portions SGe of the band-shaped portion SG of the selection gate electrode film 21.

According to the embodiments described above, it is possible to realize the semiconductor memory device of which the reliability is high, and the method for manufacturing the same.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor memory device comprising:
a multilayer body including a first insulating film, a first electrode film, a second insulating film, and a second electrode film being stacked in this order in the multilayer body, and an end portion of the first electrode film extending outside a region directly under the second electrode film in an end portion of the multilayer body;
a semiconductor pillar piercing the first electrode film and the second electrode film;
a memory film provided between the first electrode film and the semiconductor pillar and between the second electrode film and the semiconductor pillar, and the memory film being capable of storing a charge;
an interlayer insulating film provided on the end portion of the multilayer body; and
a contact piercing the interlayer insulating film, and the contact being connected to the end portion of the first electrode film,
a first portion connected to the contact in the first electrode film including a metal or a metal nitride,
a second portion surrounding the memory film in the first electrode film including silicon, and
composition of the second portion being different from composition of the first portion.

2. The device according to claim 1, further comprising:
a support including an insulating material, and the support piercing the first insulating film, a portion including the metal or the metal nitride in the first electrode film, and the second insulating film.

3. The device according to claim 1, wherein
a tip portion of the first electrode film extends outside a region directly under the second insulating film,
thickness of the tip portion is larger than thickness of a portion of the first electrode film directly under the second insulating film, and
the contact is connected to the tip portion.

4. The device according to claim 1, wherein
the first electrode film is divided into a plurality of band-shaped portions,
composition of a side portion in a width direction of the band-shaped portion is different from composition of a center portion in the width direction of the band-shaped portion,
the center portion includes silicon, and
the side portion includes a metal.

5. The device according to claim 1, wherein
composition of the second portion is different from composition of the first portion, and
the second portion includes silicon.

6. The device according to claim 1, wherein
a whole of the first electrode film is disposed directly under the second insulating film.

7. A semiconductor memory device comprising:
a multilayer body including a first insulating film, a first electrode film, a second insulating film, and a second electrode film being stacked in this order in the multilayer body, and an end portion of the first electrode film extending outside a region directly under the second electrode film in an end portion of the multilayer body;
a semiconductor pillar piercing the first insulating film, the first electrode film, the second insulating film, and the second electrode film; and
a memory film provided between the first electrode film and the semiconductor pillar and between the second electrode film and the semiconductor pillar, and the memory film being capable of storing a charge,
the first electrode film being divided into a plurality of band-shaped portions,
composition of a side portion in a width direction of the band-shaped portion being different from composition of a center portion in the width direction of the band-shaped portion,
the center portion including silicon, and
the side portion including a metal.

8. A method for manufacturing a semiconductor memory device, comprising:
forming a multilayer body by stacking a first insulating film, a first electrode film including silicon, a second insulating film, a second electrode film including silicon, and a third insulating film in this order;
forming a hole piercing the third insulating film, the second electrode film, the second insulating film, the first electrode film, and the first insulating film in the multilayer body;
forming a memory film capable of storing a charge on an inner face of the hole;
forming a semiconductor pillar on a side surface of the memory film;
removing a portion of the second electrode which is disposed in a directly above an end portion of the first electrode film, and exposing an end face of the second electrode film and an end face of the first electrode film by selectively removing an end portion of the multilayer body;
forming a first concave portion between the first insulating film and the second insulating film in the end portion of the multilayer body, and forming a second concave portion between the second insulating film and the third insulating film in the end portion of the multilayer body by moving back an exposed face of the first electrode film and an exposed face of the second electrode film with etching;
forming a conductive film including a metal or a metal nitride, so as to cover the end portion of the multilayer body, enter the first concave portion and the second concave portion, and be in contact with the first electrode film and the second electrode film;
dividing the conductive film into a portion connected to the first electrode film and a portion connected to the second electrode film by selectively removing the conductive film;
forming an interlayer insulating film on the end portion of the multilayer body; and
forming a contact piercing the interlayer insulating film, and the contact reaching a portion connected to the first electrode film of the conductive film.

9. The method according to claim 8, wherein
in the selectively removing the conductive film, the conductive film is left on an end face of the second insulating film.

10. The method according to claim 8, further comprising:
forming a support disposed within the end portion of the multilayer body, the support piercing the third insulating film, the second electrode film, and the second insulating film, and the first electrode film, and the support including an insulating material.

11. The method according to claim 8, wherein
in the selectively removing the conductive film, the conductive film is left only within the first concave portion and the second concave portion.

12. A method for manufacturing a semiconductor memory device, comprising:
forming a multilayer body by stacking a first insulating film, a first electrode film including silicon, a second insulating film, a second electrode film including silicon, and a third insulating film in order;
forming a hole piercing the third insulating film, the second electrode film, the second insulating film, the first electrode film, and the first insulating film in the multilayer body;
forming a memory film capable of storing a charge on an inner face of the hole;
forming a semiconductor pillar on a side surface of the memory film;
forming a slit dividing the first electrode film and the second electrode film respectively into a plurality of band-shaped portions in the multilayer body;
moving back an exposed face of the first electrode film and an exposed face of the second electrode film by etching the first electrode film and the second electrode film through the slit, forming a first concave portion between the first insulating film and the second insulating film in an inner face of the slit, and forming a second concave portion between the second insulating film and the third insulating film;
forming a metal film within the slit, the metal film being entered into the first concave portion and the second concave portion, and the metal film be in contact respectively with the first electrode film and the second electrode film; and
dividing the metal film into a portion disposed within the first concave portion and a portion disposed within the second concave portion by selectively removing the metal film.
